(19) United States
(12) Patent Application Publication
(10) Pub. No.: US 2025/0071916 A1
(43) Pub. Date: Feb. 27, 2025

(54) WINDING-TYPE DISPLAY DEVICE AND METHOD FOR CORRECTION PERFORMED BY WINDING-TYPE DISPLAY DEVICE

(71) Applicant: Sharp Display Technology Corporation, Kameyama City, Mie (JP)

(72) Inventors: Yixin YANG, Kameyama City, Mie (JP); Takashi KAWAMOTO, Kameyama City, Mie (JP); Shinichi KAWATO, Kameyama City, Mie (JP)

(21) Appl. No.: 18/726,805

(22) PCT Filed: Mar. 8, 2022
(86) PCT No.: PCT/JP2022/009845

§ 371 Date: Jul. 4, 2024

(51) Int. Cl. H05K 5/02; H05K 9/00

(52) U.S. Cl. CPC H05K 5/0217; H05K 9/0067

(57) ABSTRACT

A winding-type display device includes in a storage box a first roller winding a display, a correction unit correcting light luminance of the display, and a second roller winding the display wound by the first roller. Such a feature makes it possible to perform self-correction on a light-emitting device any time without giving a user an odd feeling.

### TECHNICAL FIELD

The present invention relates to a winding-type display device capable of winding and accommodating a flexible light-emitting device, and to a method for correction performed by the winding-type display device.

### BACKGROUND ART

A conventionally known display device includes: a display having, as display elements, a plurality of electro-optical elements, such as, for example, organic light-emitting diodes (OLEDs), whose luminance and chromaticity are controlled by currents; a luminance measuring unit that measures luminance of the display elements of the OLED display in a covering state; and a correction value calculating unit that corrects a data signal to be provided to each of the pixels of the respective display elements, in accordance with a result of the measurement by the luminance measuring unit.

The above configuration makes it possible to correct (self-correct) degradation and unevenness caused by deterioration over time after the use of the OLED display, in accordance with a result of measurement by the luminance measuring unit.

### CITATION LIST

### Patent Literature

[Patent Document 1] International Publication No. WO/2019/187068

### SUMMARY OF INVENTION

### Technical Problems

When the winding-type display device performs optical self-correction on a flexible light-emitting device to be wound, the light-emitting device has to be wound and released several times. Hence, when the light-emitting device is wound and released in a storage box as described in, for example, Patent Document 1, the light-emitting device gets in and out of the storage box. This might give a user an odd feeling. Furthermore, if the light-emitting device is self-corrected without giving the user an odd feeling, the self-correction needs to be performed at a time when the user does not use the winding-type display device (e.g., at midnight).

An aspect of the present invention sets out to provide a winding-type display device capable of performing self-correction on a light-emitting device anytime without giving a user an odd impression. The aspect of the present invention also sets out to provide a method for correction performed by the winding-type display device.

### Solution to Problems

A winding-type display device according to an aspect of the present invention includes: a light-emitting device flexible and having a light-emitting surface; a first roller that winds the light-emitting device; a storage box storing the first roller; a correction data obtaining device that obtains correction data in the storage box when the light-emitting device is either wound or released, the correction data being used for correcting the light-emitting device; a correction device that corrects light luminance of the light-emitting device, in accordance with the correction data obtained by the correction data obtaining device; and a second roller disposed in the storage box, and winding the light-emitting device, wound by the first roller, when the correction data obtaining device obtains the correction data on the light-emitting device.

A method for correction performed by a winding-type display device according to an aspect of the present invention includes: a first step of winding a light-emitting device, flexible and having a light-emitting surface, around a first roller in a storage box, with the light-emitting surface facing outward; a second step of forwarding an end portion of the light-emitting device, wound by the first roller at the first step, to a second roller provided in the storage box; a third step of winding the light-emitting device by the second roller to which the end portion of the light-emitting device is forwarded at the second step; a forth step of detecting, during the third step, light-emission information by a light-emission-information reading device from the light-emitting surface of the light-emitting device; and a fifth step of correcting light luminance of the light-emitting device in accordance with the light-emission information read by the light-emission-information reading device at the fourth step.

### Advantageous Effects of Invention

An aspect of the present invention makes it possible to perform self-correction on a light-emitting device any time without giving a user an odd feeling.

### BRIEF DESCRIPTION OF DRAWINGS

FIG. 1 is a view of a configuration of a winding-type display device according to a first embodiment of the present invention.

FIG. 2 is a view of the winding-type display device in FIG. 1, showing that a display device is wound by a first roller.

FIG. 3 is a view of the winding-type display device in FIG. 1, showing how to read light-emission information on a light-emitting surface of the display device.

FIG. 4 is a view of a configuration of a modification of the winding-type display device illustrated in FIG. 1.

FIG. 5 is an enlarged view of a main component of the modification illustrated in FIG. 4.

FIG. 6 is a perspective view of a read sensor provided to the winding-type display device illustrated in FIGS. 1 and 4.

FIG. 7 is a perspective view of a modification of the read sensor provided to the winding-type display device illustrated in FIGS. 1 and 4.

FIG. 8 is a flowchart showing how the winding-type display device illustrated in FIGS. 1 and 4 performs a white one-tone correction.

FIG. 9 is a flowchart showing details of a step of reading and adjusting a light-emitting screen according to the flowchart of the white one-tone correction in FIG. 8.

FIG. 10 is a flowchart showing how the winding-type display device illustrated in FIGS. 1 and 4 performs a white multiple-tone correction.

FIG. 11 is a flowchart showing how the winding-type display device illustrated in FIGS. 1 and 4 performs another white multiple-tone correction.

FIG. 12 is a flowchart showing how the winding-type display device illustrated in FIGS. 1 and 4 performs an RGB monochromatic one-tone correction.

FIG. 13 is a view of a configuration of a winding-type display device according to a second embodiment of the present invention.

FIG. 14 is a view of the winding-type display device in FIG. 13, showing that the display device is wound by the first roller.

FIG. 15 is a view of a configuration of a modification of the winding-type display device illustrated in FIG. 13.

FIG. 16 is a view of the winding-type display device in FIG. 15, showing that the display device is wound by the first roller.

FIG. 17 is a view of a configuration of a modification of the winding-type display device illustrated in FIG. 13.

FIG. 18 is a view of the winding-type display device in FIG. 17, showing that the display device is wound by the first roller.

FIG. 19 is a perspective view of an electrostatic control device provided to the winding-type display device illustrated in FIGS. 15 and 17.

FIG. 20 is a perspective view of a modification of the electrostatic control device provided to the winding-type display device illustrated in FIGS. 15 and 17.

### DESCRIPTION OF EMBODIMENTS

### First Embodiment

An embodiment of the present invention will be described below in details.

### Outline of Winding-Type Display Device 1

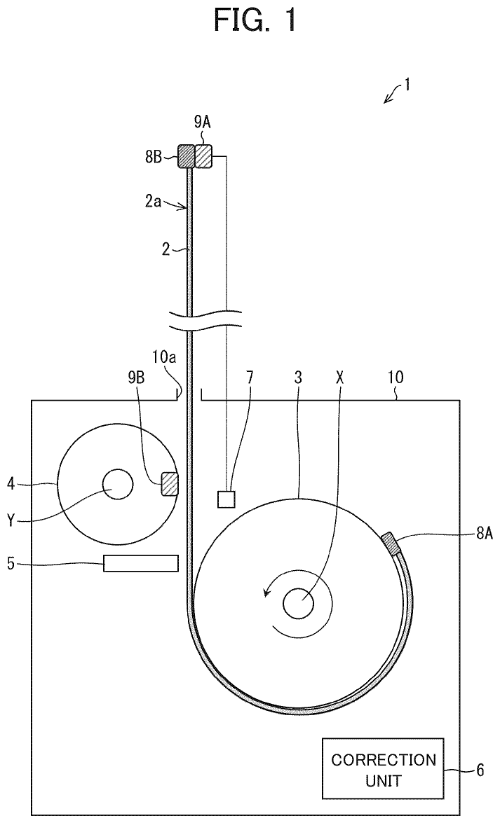

FIG. 1 is a view of a configuration of a winding-type display device 1 according to an embodiment. The winding-type display device 1 includes: a display 2 (i.e., a light-emitting device) that is flexible; a first roller 3; a second roller 4; a read sensor (i.e., a light-emission-information reading device and a correction data obtaining device) 5; a correction unit (i.e., a correction device) 6; and a drawing device 7.

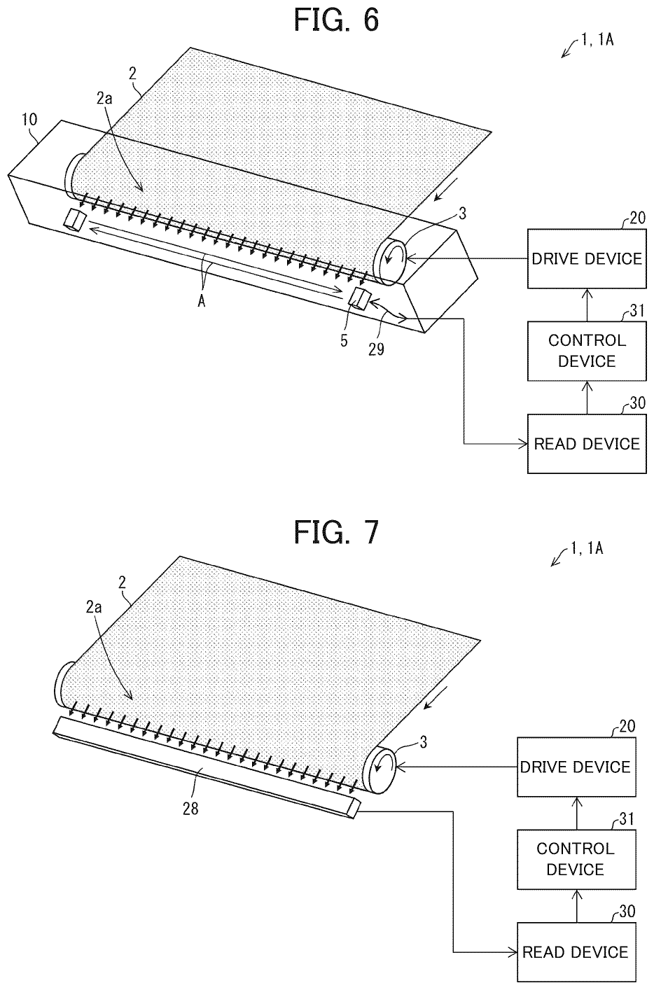

The first roller 3 is a roller to wind the display 2 with a light-emitting surface 2a of the display 2 facing outward, and to release the wound display 2. The second roller 4 is a roller to wind the display 2, which is wound by the first roller 3, with the light-emitting surface 2a of the display 2 facing inward, and to release the wound display 2. The first roller 3 is supported rotatably about a rotation shaft X. Whereas, the second roller 4 is supported rotatably about a rotation shaft Y. That is, the second roller 4 rotates in a desired direction when a drive device 20 (see FIG. 6) such as a not-shown drive motor rotates the rotation shaft Y. For example, when the correction unit 6 corrects (self-corrects) the display 2, the second roller 4 rotates in a direction for winding the display 2 wound by the first roller 3. Details will be described later as to drive control performed by the drive device 20 that drives the second roller 4.

The winding-type display device 1 has a function of correcting a light-emission state of the light-emitting surface 2a of the display 2. In order to achieve this function, the winding-type display device 1 includes the read sensor 5 and the correction unit 6. The read sensor 5 is an optical sensor that reads light-emission information on the light-emitting surface 2a of the display 2 as correction data required for correcting light luminance of the light-emitting surface 2a of the display 2. The correction unit 6 corrects the light luminance of the light-emitting surface 2a of the display 2, in accordance with the light-emission information (the correction data) read by the read sensor 5. Details will be described later as to the correction of the light luminance.

The winding-type display device 1 further includes a storage box 10 to store, and block dust and external light from, the first roller 3, the second roller 4, the read sensor 5, the correction unit 6, and the drawing device 7. The storage box 10 has an opening 10a through which the display 2 enters and exits.

The drawing device 7 is a device to draw out the display 2, which is wound by the first roller 3, through the opening 10a of the storage box 10, and to draw in the drawn-out display 2 through the opening 10a of the storage box 10. That is, in the winding-type display device 1, the drawing device 7 draws out the display 2 when necessary, and draws in the display 2 when no longer necessary.

The display 2 has: one end provided with a first fastener 8A that fastens the one end to a surface of the first roller 3; and another end provided with a second fastener 8B that fastens the other end to a first fastening device 9A to be drawn out from the drawing device 7. Here, the first fastener 8A may be a member to be fastened to the surface of the first roller 3. Whereas, the second fastener 8B is made of a magnetic material such as iron, in order to be fastened to the first fastening device 9A. Hence, the first fastening device 9A is preferably an electromagnet. This is because the first fastening device 9A easily attaches and detaches the second fastener 8B by ON and OFF of power.

Furthermore, the second roller 4 has a second fastening device 9B close to a surface of the second roller 4. The second fastening device 9B includes an electromagnet, and easily attaches and detaches the second fastener 8B of the display 2 by ON and OFF of power.

Note that, in the winding-type display device 1, the flexible display 2 may be replaced with a flexible light-emitting product. Examples of the flexible light-emitting product may include a flexible lighting device and a matrix OLED lamp.

The winding-type display device 1 in the above configuration corrects the light luminance of the light-emitting surface 2a of the display 2 as will be described below.

### Operation for Correcting Light Luminance

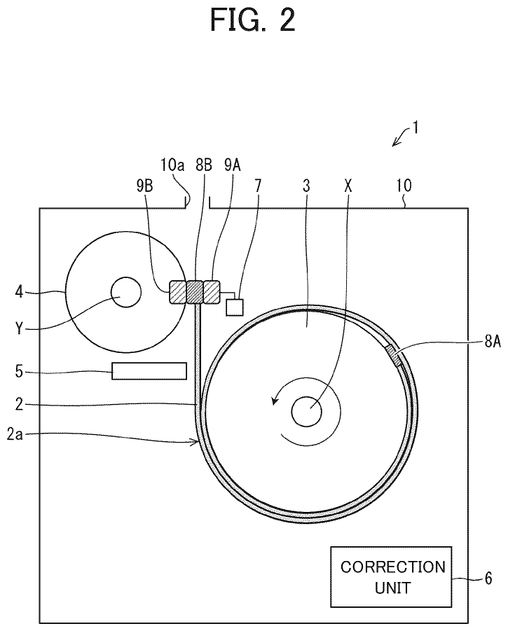

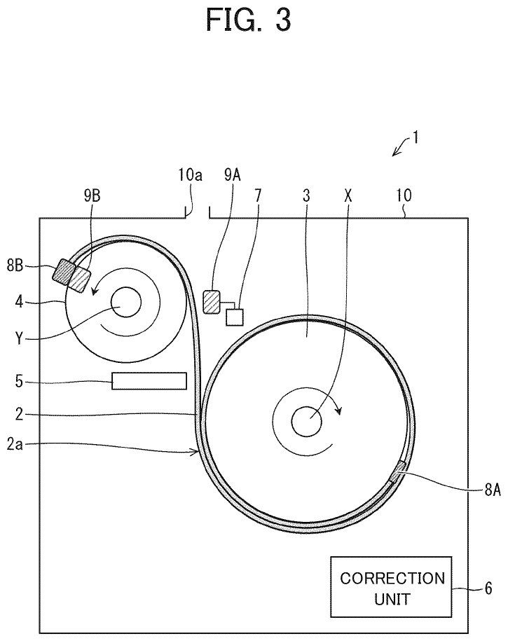

FIG. 2 is a view showing that the display 2 is wound by the first roller 3. FIG. 3 is a view showing that the display 2 is wound by the second roller 4. First, as illustrated in FIG. 1, the display 2 is drawn by the drawing device 7 to a predetermined position (i.e., a viewing state). Then, as illustrated in FIG. 2, the viewing state transits to a state (i.e., a storage state) in which the display 2 is wound around the first roller 3 by the drawing device 7, and the second fastener 8B is stored in the storage box 10. That is, the display 2 is wound around the first roller 3 in the storage box 10, with the light-emitting surface 2a of the display 2 facing outward (i.e., a first step). In this storage state, the second fastener 8B of the display 2 is fastened to the first fastening device 9A. In this state, the second fastener 8B is positioned near the second fastening device 9B of the second roller 4. In the storage state, the first fastening device 9A is in a power ON state, and the second fastening device 9B is in a power OFF state. In this storage state, when the display 2 needs to be wound by the second roller 4; that is, for example, when the read sensor 5 reads the light-emission information on the light-emitting surface 2a of the display 2, the second fastening device 9B turns ON to fasten the second fastener 8B. Whereas, the first fastening device 9A turns OFF to unfasten the second fastener 8B. Thus, as illustrated in FIG. 3, the display 2 can be wound by the second roller 4. That is, an end portion of the display 2 wound by the first roller 3 is forwarded to the second roller 4 provided in the storage box 10 (i.e., a second step). Specifically, the first fastener 8A, the second fastener 8B, the first fastening device 9A, and the second fastening device 9B function as a forwarding mechanism to forward the display 2 between the first roller 3 and the second roller 4 in the storage box 10. This forwarding mechanism forwards the display 2: from the first roller 3 to the second roller 4 when the correction unit 6 starts to correct the display 2; and from the second roller 4 to the first roller 3 after the correction unit 6 finishes correcting the display 2.

The second roller 4 may move toward the first roller 3. For example, when the correction unit 6 corrects the display 2, the second roller 4 is moved toward the first roller 3 as soon as the first roller 3 finishes winding the display 2, so that the second fastener 8B of the display 2 and the second fastening device 9B of the second roller 4 are brought close to each other. Hence, the second fastener 8B of the display 2 can be reliably fastened by the second fastening device 9B of the second roller 4. Thus, the second roller 4, to which the end portion of the display 2 is forwarded, winds the display 2 (i.e., a third step). Here, the second roller 4 winds the display 2 with the light-emitting surface 2a facing inward. Hence, the second roller 4 is preferably smaller in diameter than the first roller 3. This is because, if the second roller 4 is smaller in diameter than the first roller 3, a wider area is available for reading the light-emitting surface 2a of the display 2.

While the display 2 transits from the storage state in FIG. 2 to the state in FIG. 3, the read sensor 5 reads the light-emission information on the light-emitting surface 2a of the display 2 (i.e., a fourth step). That is, while the second roller 4 winds the display 2, the read sensor 5 reads the light-emission information on the light-emitting surface 2a. Using the light-emission information read by the read sensor 5, the correction unit 6 corrects the light luminance of the light-emitting surface 2a of the display 2 (i.e., a fifth step).

### Advantageous Effects

The above winding-type display device 1 reads the light-emission information on the light-emitting surface 2a of the display device 2 while the second roller 4 winds the display 2 wound by the first roller 3. Such a feature eliminates the need for drawing in and out the display device 2 to and from the storage box 10 in reading the light-emission information on the light-emitting surface 2a of the display 2. Thanks to such a feature, the user does not have an odd feeling when the display 2 unexpectedly gets in and out of the storage box 10. Moreover, the feature allows the display 2 to be corrected in the storage box 10, which keeps correction of the display 2 out of view. Hence, the user does not have to designate a time for correcting the display 2.

Furthermore, the above winding-type display device 1 is light in weight and small in size because all the constituent features are stored in the storage box 10. Hence, the winding-type display device 1 is portable.

### Modification

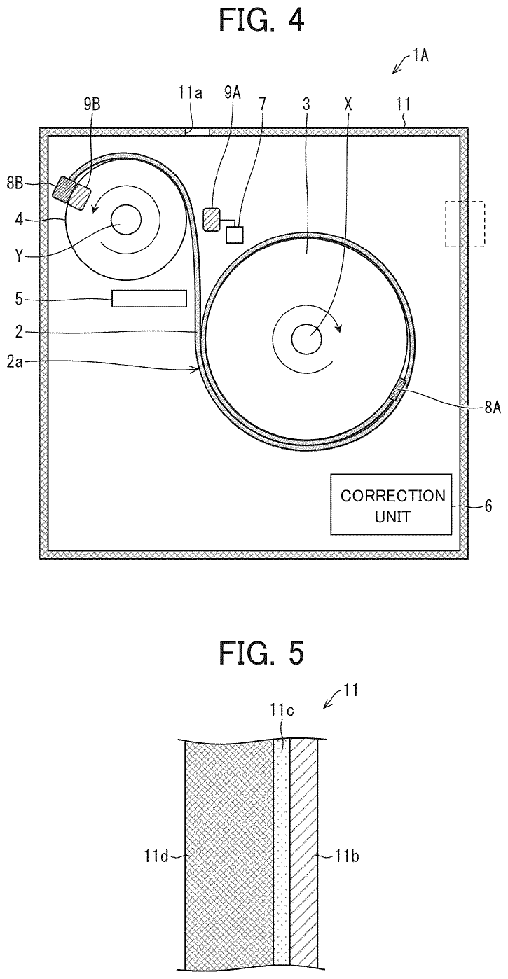

FIG. 4 is a view of a configuration of a winding-type display device 1A; that is, a modification of the winding-type display device 1 illustrated in FIG. 1. FIG. 5 is an enlarged view of a main component of the winding-type display device 1A illustrated in FIG. 4.

Although basically having the same configuration, the winding-type display device 1A and the winding-type display device 1 illustrated in FIG. 1 are different in that the winding-type display device 1A includes a storage box 11 subjected to noise-insulating processing. Although the storage box 10 of the winding-type display device 1 illustrated in FIG. 1 provides a certain degree of noise-insulating effect, the storage box 11 is used to enhance the noise-insulating performance. The storage box 11 preferably has a light-shielding function and a sound-insulating function so that light and sound do not leak outside. Hence, for example, as illustrated in FIG. 5, a noise insulating material 11d is attached through a sealing material 11c to a box wall 11b disposed outside.

The above winding-type display device 1A uses the storage box 11 having a high noise-insulating effect. In correcting the light luminance of the light-emitting surface 2a of the display device 2, the storage box 11 can block such noises as noises of the first roller 3 and the second roller 4 rotating in the storage box 11. Such a feature can almost eliminate noise generated when the correction is made in the storage box 11. Hence, the winding-type display device 1A can correct the light luminance of the light-emitting surface 2a of the display 2 anytime and anywhere.

### Operation for Reading Light-Emission Information

FIG. 6 is a perspective view of a read sensor 5 provided to the winding-type display devices 1 and 1A. Identical reference signs are used to denote the identical constituent elements described before. Such constituent elements will not be elaborated upon repeatedly. Note that no difference is found between the winding-type display device 1 and the winding-type display device 1A as to reading by the read sensor 5 of the light-emission information on the light-emitting surface 2a of the display device 2. Hereinafter, the description below will be given with reference to the winding-type display device 1.

The read sensor 5 reciprocates between one end and another end of the display 2 along arrows A to detect the light-emission information from the light-emitting surface 2a of the display 2.

The winding-type display device 1 includes: a wire 29 that is flexible and connected to the read sensor 5; a read device 30 connected to the wire 29 to read the light-emission information detected by the read sensor 5 from the light-emitting surface 2a of the display 2; and a control device 31 that controls the drive device 20 in accordance with progress of reading the light-emission information by the read device 30.

While the first roller 3 releases the display 2 and the second roller 4 winds the display 2 stepwise, the read sensor 5 scans the light-emitting surface 2a of the display 2 along the arrows A to detect the light-emission information, and inputs the read light-emission information through the wire 29 to the read device 30.

The drive device 20, the control device 31, and the read device 30 may be provided in the storage box 10.

FIG. 7 is a perspective view of a read sensor 28 provided to the winding-type display devices 1 and 1A. Identical reference signs are used to denote the identical constituent elements described before. Such constituent elements will not be elaborated upon repeatedly. The winding-type display device 1 may include a read sensor 28 instead of the read sensor 5. The read sensor 28 is a linear read sensor extending between one end and another end of the display 2.

While the first roller 3 releases the display 2 and the second roller 4 winds the display 2 stepwise, the read sensor 28 detects the light-emission information from the one end to the other end of the light-emitting surface 2a of the display 2, and inputs the detected light-emission information to the read device 30.

Correction of Light Luminance Described below will be how to correct the light luminance of the light-emitting surface 2a of the display device 2 for the winding-type display device 1 and the winding-type display device 1a.

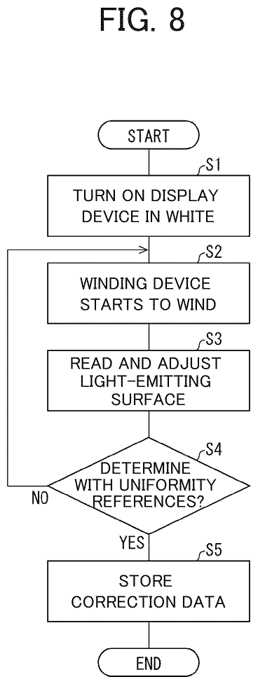

FIG. 8 is a flowchart showing how the winding-type display device 1 performs a white one-tone correction.

First, the display 2 is released from the first roller 3. Immediately before being wound by the second roller 4, the display 2 is turned ON in white (Step S1). Then, the second roller 4 starts to wind the display 2 (Step S2). Next, the read sensor 5 reads the light-emitting surface 2a of the display 2 turned ON in white (Step S3).

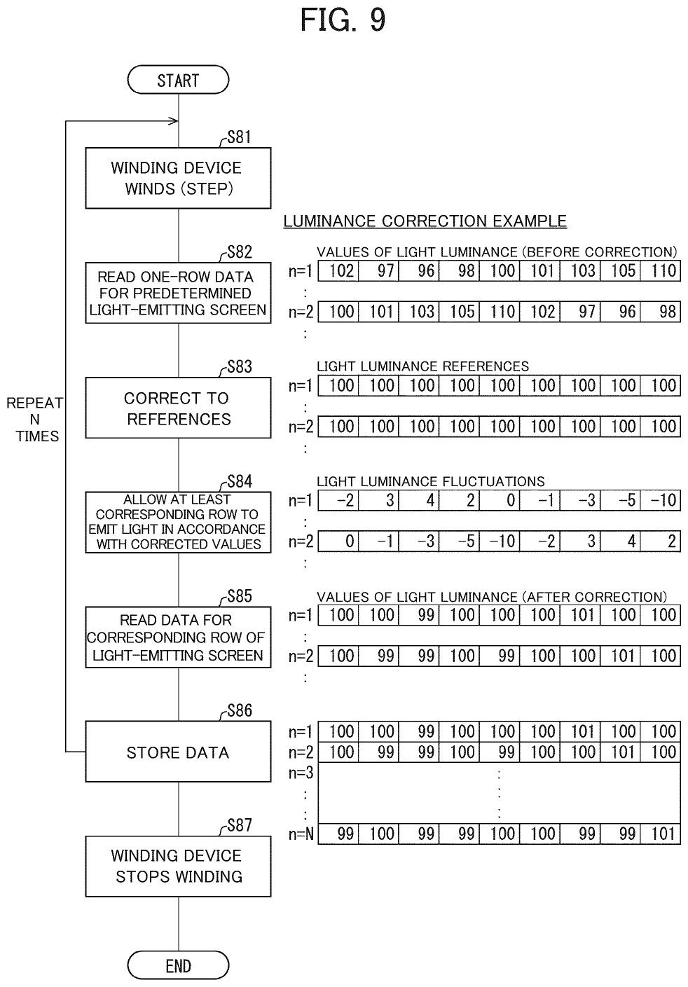

FIG. 9 is a flowchart showing details of a step of reading and adjusting a light-emitting screen (Step S3) according to the flowchart of the white one-tone correction in FIG. 8.

First, the second roller 4 winds the display 2 stepwise (Step S81). Then, the read sensor 5 reads a one-row data set for a predetermined light-emitting screen on the light-emitting surface 2a of the display 2 (Step S82).

Next, the correction unit 6 corrects the one-row data set, read by the read sensor 5 for the predetermined light-emitting screen, to light luminance references (Step S83). After that, in accordance with corrected values obtained at Step S83, a row corresponding to the one-row data set of the display 2 is allowed to emit light (Step S84).

Then, the read sensor 5 reads again the one-row data set for the predetermined light-emitting screen of the display 2 (Step S85). Next, the correction unit 6 stores the one-row data set, read at Step S85 for the predetermined light-emitting screen, on a not-shown temporary storage unit (Step S86).

The winding-type display device 1 repeats the processing of Steps S81 to S86 n=N times.

After that, the second roller 4 stops winding the display 2 (Step S87).

For example, when the second roller 4 proceeds with the winding of the display 2 row by row for the predetermined light-emitting screen of the display 2, first, a lowermost row of the predetermined light-emitting screen is subjected to processing including: emitting light and measuring (Step S82); obtaining a corrected value (Step S83); making a correction (emitting light) (Step S84); measuring again (Step S85), and storing (Step S86). Then, the second roller 4 winds the display 2 for one row. A second row of the predetermined light-emitting screen from the lowermost row is subjected to processing including: emitting light and measuring (Step S82); obtaining corrected values (Step S83); making a correction (emitting light) (Step S84); measuring again (Step S85); and storing (Step S86).

Next, the second roller 4 winds the display 2 for another one row. A third row of the predetermined light-emitting screen from the lowermost row is subjected to the same processing. The same processing is performed on the N-th row of the predetermined light-emitting screen from the lowermost row.

For example, in the lowermost row of the predetermined light-emitting screen, if the one-row data set read at Step S82 is represented by values 102, 97, 96, 98, 100, 101, 103, 105, 110, fluctuations of light luminance data to allow the display 2 to emit light are represented by values −2, 3, 4, 2, 0, 0, −1, −3, −5, −10 with respect to the light luminance references 100, 100, 100, 100, 100, 100, 100, 100, 100.

Then, in accordance with corrected values obtained from the light luminance data, a row corresponding to the one-row data set of the display 2 is allowed to emit light (Step S84). Next, the read sensor 5 reads again the one-row data set for the predetermined light-emitting screen of the display 2 (Step S85). If the one-row data set read at Step S85 for the predetermined light-emitting screen is represented by values 100, 100, 99, 100, 100, 100, 101, 100, 100, the one-row data set is stored on the temporary storage unit (Step S86).

Note that the above processing can be performed in an unwinding operation. In such a case, the processing is performed from an uppermost row of the predetermined light-emitting screen. Furthermore, each winding may involve winding multiple rows at a time.

Then, the correction unit 6 calculates uniformity (variation) of the N one-row data sets, for the luminance, measured again at Step S85 and stored on the temporary storage unit, and then, the correction unit 6 compares the calculated uniformity (variation) with a designated target uniformity value. If the uniformity (variation) is larger than, or equal to, the designated target uniformity value (NO at Step S4), the processing returns to Step S2. If the uniformity (variation) is smaller than the designated target uniformity value (YES at Step S4), the correction unit 6 stores the N one-row data sets on a not-shown storage unit (Step S5).

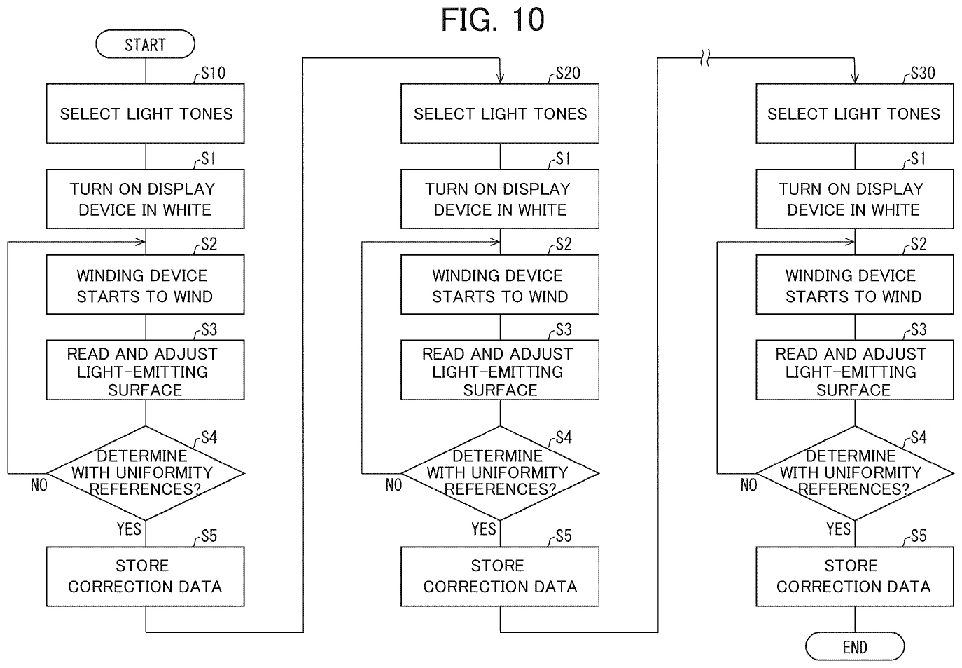

FIG. 10 is a flowchart showing how the winding-type display device 1 performs a white multiple-tone correction. Identical reference signs are used to denote the identical constituent elements described before. Such constituent elements will not be elaborated upon repeatedly.

First, for example, 255 of light tones are selected (Step S10). Then, the display 2 is unwound out of the storage box 11 and turned ON in white (Step S1). Next, the second roller 4 starts to wind the display 2 (Step S2). After that, the read sensor 5 reads the light-emitting surface 2a of the display 2 turned ON in white (Step S3).

Then, the correction unit 6 calculates uniformity (variation) of the N one-row data sets, for the luminance, measured again at Step S85 and stored on the temporary storage unit, and then, the correction unit 6 compares the calculated uniformity (variation) with a designated target uniformity value. If the uniformity (variation) is larger than, or equal to, the designated target uniformity value (NO at Step S4), the processing returns to Step S2. If the uniformity (variation) is smaller than the designated target uniformity value (YES at Step S4), the correction unit 6 stores the N one-row data sets on a not-shown storage unit (Step S5).

Then, the display 2 is unwound. After that, for example, 120 of other light tones are selected (Step S20). From then on, the processing of Steps S1 to S5 is carried out in the same manner. Next, after the display 2 is unwound, for example, 60 of still other light tones are selected (Step S30). From then on, the processing of Steps S1 to S5 is carried out in the same manner.

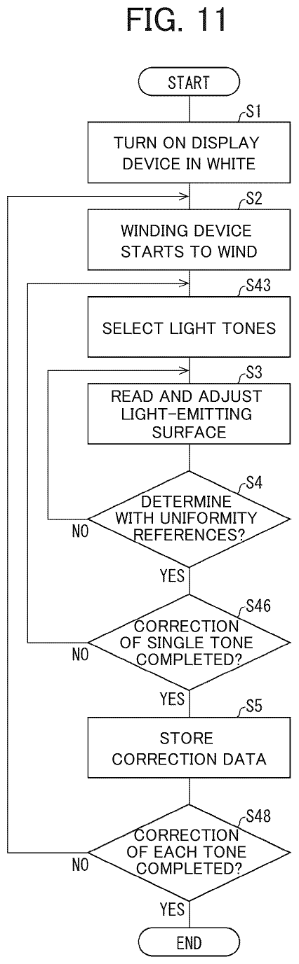

FIG. 11 is a flowchart showing how the winding-type display device 1 performs another white multiple-tone correction. Identical reference signs are used to denote the identical constituent elements described before. Such constituent elements will not be elaborated upon repeatedly.

First, the display 2 is unwound out of the storage box 10, and turned ON in white (Step S1). Then, the second roller 4 starts to wind the display 2 (Step S2).

Next, light tones are selected (Step S43). After that, the read sensor 5 reads the light-emitting surface 2a of the display 2 turned ON in white (Step S3).

Then, the correction unit 6 calculates uniformity (variation) of the N one-row data sets, for the luminance, measured again at Step S85 and stored on the temporary storage unit, and then, the correction unit 6 compares the calculated uniformity (variation) with a designated target uniformity value. If the uniformity (variation) is larger than, or equal to, the designated target uniformity value (NO at Step S4), the processing returns to Step S3. If the uniformity (variation) is smaller than the designated target uniformity value (YES at Step S4), a determination is made whether correction of a single tone has been completed (Step S46). If the determination indicates that the correction of the single tone has not been completed (NO at Step S46), the processing returns to Step S43. If the determination indicates that the correction of the single tone has been completed (YES at Step S46), the correction unit 6 stores the N one-row data sets on a not-shown storage unit (Step S5).

Next, a determination is made whether the correction of each of the tones has been completed (Step S48). If the determination indicates that the correction of each tone has not been completed (NO at Step S48), the processing returns to Step S2. If the determination indicates that the correction of each tone has been completed (YES at Step S48), the processing ends.

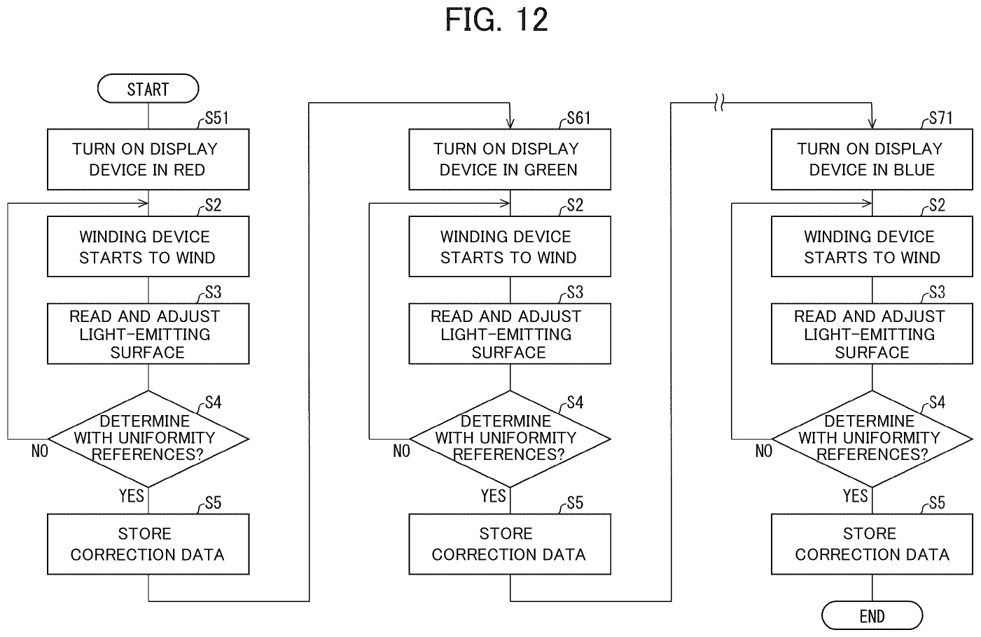

FIG. 12 is a flowchart showing how the winding-type display device 1 performs an RGB monochromatic one-tone correction. Identical reference signs are used to denote the identical constituent elements described before. Such constituent elements will not be elaborated upon repeatedly.

First, the display 2 is unwound out of the storage box 10, and turned ON in red (Step S51). Then, the second roller 4 starts to wind the display 2 (Step S2). Next, the read sensor 5 reads the light-emitting surface 2a of the display 2 turned ON in red (Step S3).

Next, the correction unit 6 calculates uniformity (variation) of the N one-row data sets, for the luminance, measured again at Step S85 and stored on the temporary storage unit, and then, the correction unit 6 compares the calculated uniformity (variation) with a designated target uniformity value. If the uniformity (variation) is larger than, or equal to, the designated target uniformity value (NO at Step S4), the processing returns to Step S2. If the uniformity (variation) is smaller than the designated target uniformity value (YES at Step S4), the correction unit 6 stores the N one-row data sets on a not-shown storage unit (Step S5).

Then, the display 2 is unwound out of the storage box 10 and turned ON in green (Step S61). From then on, the processing of Steps S2 to S5 is carried out in the same manner. Then, the display 2 is unwound out of the storage box 10 and turned ON in blue (Step S61). From then on, the processing of Steps S2 to S5 is carried out in the same manner.

### Second Embodiment

Another embodiment of the present invention will be described below. Note that, for convenience in description, like reference signs designate members having identical functions between this embodiment and the above embodiment. These members will not be elaborated upon repeatedly.

### Outline of Winding-Type Display Device 1B

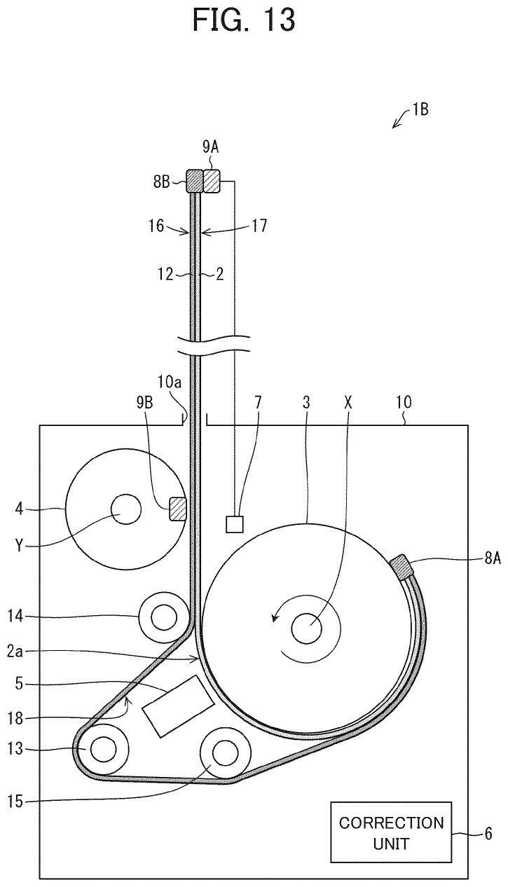

FIG. 13 is a view of a configuration of a winding-type display device 1B according to an embodiment. The winding-type display device 1B includes: the display 2 (i.e., a light-emitting device) that is flexible; a protective film 12 laminated on the light-emitting surface 2a of the display 2; the first roller 3; the second roller 4; the read sensor 5; the correction unit 6; the drawing device 7; and a first guide member 13. The first roller 3 winds the protective film 12 and the display 2, with the protective film 12 provided outside the display 2. When the protective film 12 and the display 2 are wound by the first roller 3, the protective film 12 is delaminated from the display 2. The delaminated protective film 12 is wound around the first guide member 13. The read sensor 5 is disposed between the first guide member 13 and the first roller 3, in order to detect light-emission information from the light-emitting surface 2a, of the display 2, from which the protective film 12 is delaminated.

Note that, the flexible display 2 may be replaced with a flexible light-emitting product. Examples of the flexible light-emitting product may include a flexible lighting device and a matrix OLED lamp.

When the light-emitting surface 2a of the display 2 is wound by the first roller 3 downstream of a position in which the read sensor 5 detects light-emission information, the protective film 12 wound by the first guide member 13 is laminated again on the light-emitting surface 2a of the display 2.

The protective film 12 has: a first surface 16 across from the display 2; and a second surface 18 toward the display 2.

The winding-type display device 1B further includes a second guide member 14 provided in a position in which the display device 2 in winding starts to come into contact with the first roller 3. The second guide member 14 winds the protective film 12 across from the display 2 in relation to the protective film 12.

The winding-type display device 1B further includes a third guide member 15 disposed between the first guide member 13 and the first roller 3. The third guide member 15 winds the protective film 12 across from the first roller 3.

The winding-type display device 1B further includes the storage box 10 to store, and block dust and external light from, the first roller 3, the first to third guide members 13 to 15, and the read sensor 5. The storage box 10 has the opening 10a through which the display 2 laminated with the protective film 12 enters and exits.

If the diameter of the first guide member 13 is large, the third guide member 15 may be omitted. The second guide member 14 is disposed preferably near the read sensor 5.

After the read sensor 5 detects the light-emission information, the protective film 12 is quickly laminated again on the display 2 to keep the display 2 from dust.

The first to third guide members 13 to 15 are preferably rotatable in accordance with winding of the protective film 12 by the first roller 3. The display 2 preferably includes OLEDs.

The winding-type display device 1B further includes: the first fastener 8A that fastens one end of the protective film 12 to one end of the display device 2; the second fastener 8B that fastens another end of the protective film 12 to another end of the display 2; and the drawing device 7 that draws the display 2 and the protective film 12 out of the box 10. The second fastener 8B is fastened to the first fastening device 9A drawn out from the drawing device 7.

Here, the first fastener 8A may be a member to be fastened to the surface of the first roller 3. Whereas, the second fastener 8B is made of a magnetic material such as iron, in order to be fastened to the first fastening device 9A. Hence, the first fastening device 9A is made of an electromagnet. That is, the first fastening device 9A attaches and detaches the second fastener 8B by ON and OFF of power.

Furthermore, the second roller 4 has the second fastening device 9B close to the surface of the second roller 4. The second fastening device 9B is formed of an electromagnet, and easily attaches and detaches the second fastener 8B of the display 2 by ON and OFF of power.

The winding-type display device 1B further includes the correction unit 6 that corrects light luminance of the light-emitting surface 2a of the display device 2 in accordance with light-emission information detected by the read sensor 5 from the light-emitting surface 2a of the display 2. The correction unit 6 is stored in the storage box 10.

### Operation for Correcting Light Luminance

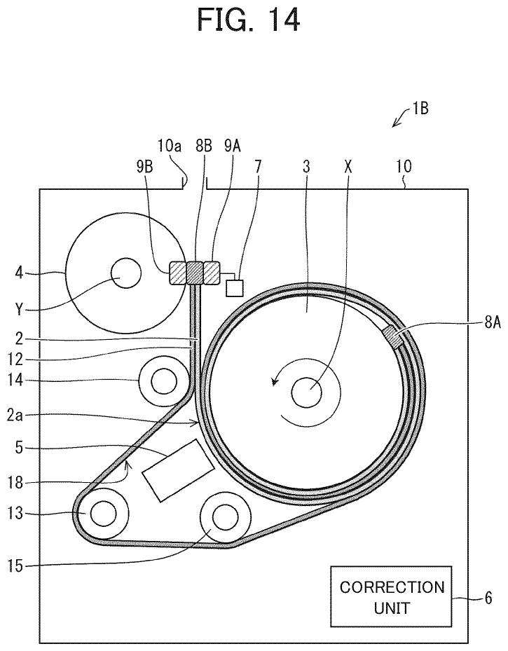

FIG. 14 is a view when the display 2 is wound by the first roller 3. First, as illustrated in FIG. 13, the display 2 is drawn by the drawing device 7 to a predetermined position (i.e., a viewing state). Then, as illustrated in FIG. 14, the viewing state transits to a state (i.e., a storage state) in which the display 2 is wound around the first roller 3 by the drawing device 7, and the second fastener 8B is stored in the storage box 10. In this storage state, the second fastener 8B of the display 2 is fastened to the first fastening device 9A. In this state, the second fastener 8B is positioned near the second fastening device 9B of the second roller 4. In the storage state, the first fastening device 9A is in a power ON state, and the second fastening device 9B is in a power OFF state. In this storage state, when the display 2 needs to be wound by the second roller 4; that is, for example, when the read sensor 5 reads the light-emission information on the light-emitting surface 2a of the display 2, the second fastening device 9B turns ON to fasten the second fastener 8B. Whereas, the first fastening device 9A turns OFF to unfasten the second fastener 8B. Thus, the display 2 can be wound by the second roller 4.

In the storage state in FIG. 14, the second roller 4 winds the display 2. Simultaneously, the read sensor 5 reads the light-emission information on the light-emitting surface 2a of the display 2. Using the light-emission information read by the read sensor 5, the correction unit 6 corrects the light luminance of the light-emitting surface 2a of the display 2.

### Advantageous Effects

The above winding-type display device 1B reads the light-emission information on the light-emitting surface 2a of the display device 2 while the second roller 4 winds the display 2 wound by the first roller 3. Such a feature eliminates the need for drawing in and out the display device 2 to and from the storage box 10, in reading the light-emission information on the light-emitting surface 2a of the display 2. Thanks to such a feature, the user does not have an odd feeling when the display 2 unexpectedly gets in and out of the storage box 10. Moreover, the feature allows the display 2 to be corrected in the storage box 10, which keeps correction of the display 2 out of view. Hence, the user does not have to designate a time for correcting the light-emitting device. Furthermore, the read sensor 5 can read the light-emission information while the protective film 12 for protecting the light-emitting surface 2a of the display 2 is removed. Such a feature makes it possible to read more accurate light-emission information.

### First Modification

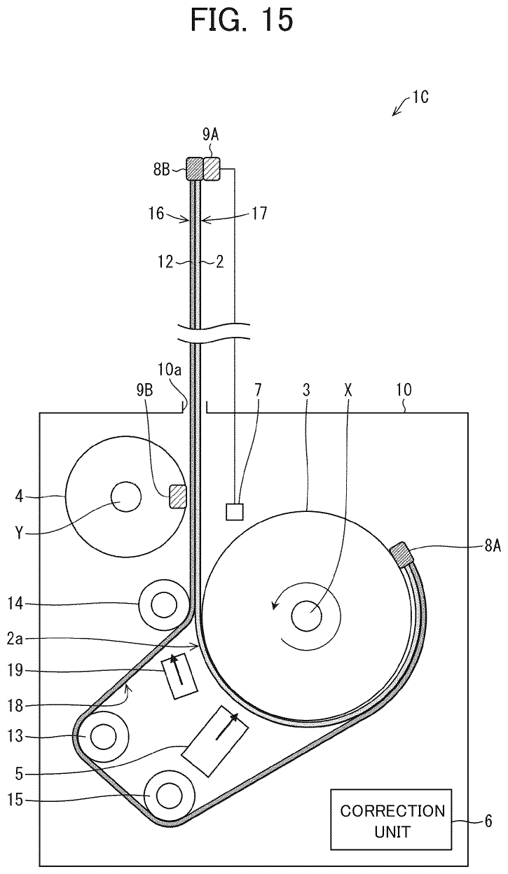

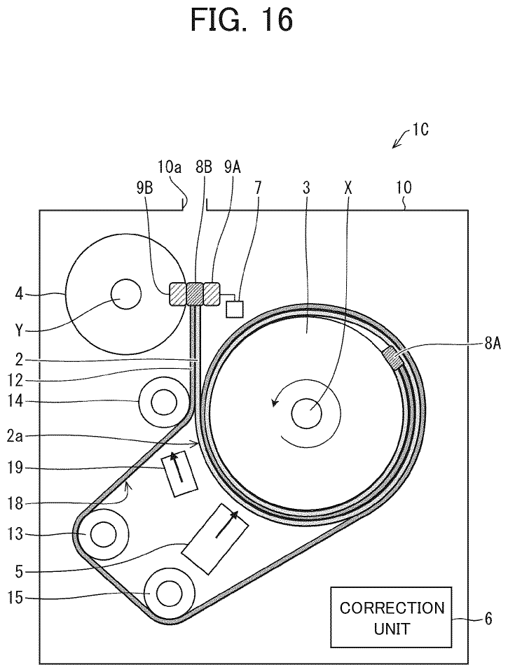

FIGS. 15 and 16 are views of a configuration of a winding-type display device 1C according to a modification. Identical reference signs are used to denote the identical constituent elements between the winding-type display device 1C and the winding-type display device 1B. Such constituent elements will not be elaborated upon repeatedly.

The winding-type display device 1C further includes: an electrostatic control device 19 disposed between the first guide member 13 and the first roller 3, in order to control, by plasma, static electricity generated when the protective film 12 is delaminated from the display 2. The electrostatic control device 19 controls attraction force between the protective film 12 and the display 2.

Note that the first modification exemplifies a case where the protective film 12 and the display 2 are laminated together by electrostatic force. Alternatively, the protective film 12 and the display 2 may be laminated together with an adhesive layer.

The storage box 10 keeps the dust on the first surface 16 of the protective film 12 from the light-emitting surface 2a, of the display 2, from which the protective film 12 is delaminated.

A problem that might occur is generation of static electricity when the protective film 12 and the display 2 are laminated and delaminated.

Thus, as illustrated in FIG. 15, the electrostatic control device 19 is provided in the storage box 10 to control static electricity generated when the protective film 12 and the display 2 are laminated and delaminated. Hence, the controlled static electricity facilitates the lamination and the delamination.

In order to facilitate the lamination and the delamination of the protective film 12 and the display 2, the electrostatic control device 19 is provided to control electrostatic when the protective film 12 and the display 2 are laminated and delaminated. The protective film 12 may be an ambient-light antireflection film.

### Second Modification

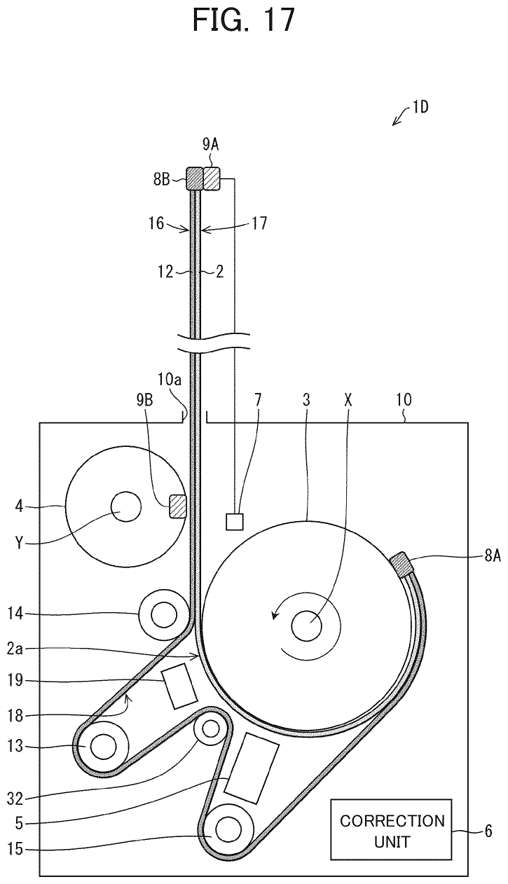

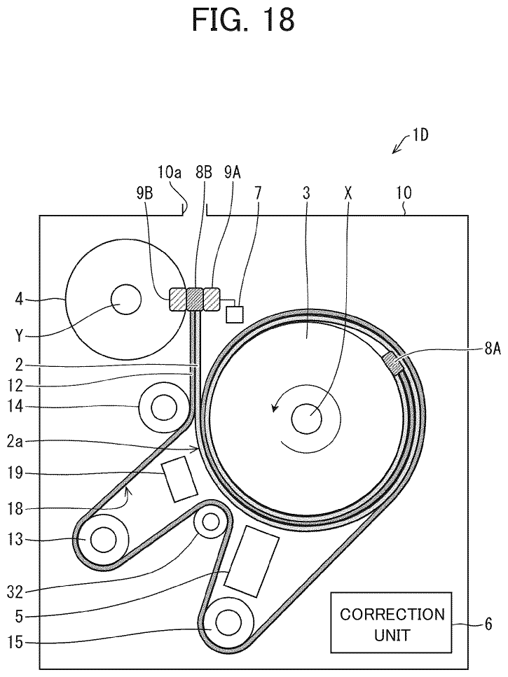

FIGS. 17 and 18 are views of a configuration of a winding-type display device 1D according to another modification. Identical reference signs are used to denote the identical constituent elements between the winding-type display device 1D and the winding-type display device 1C. Such constituent elements will not be elaborated upon repeatedly. The first guide member 13 is disposed across the electrostatic control device 19 from the first roller 3.

The winding-type display device 1D includes the third guide member 15 disposed across the read sensor 5 from the first roller 3, and provided to wind the protective film 12 to be wound by the first roller 3, and further includes a fourth guide member 32 disposed between the first guide member 13 and the third guide member 15, and provided to wind the protective film 12 across from the display 2 in relation to the protective film 12. The fourth guide member 32 can reduce influence of the plasma from the electrostatic control device 19 on the read sensor 5.

The storage box 10 keeps the dust on the first surface 16 of the protective film 12 from the light-emitting surface 2a, of the display 2, from which the protective film 12 is delaminated.

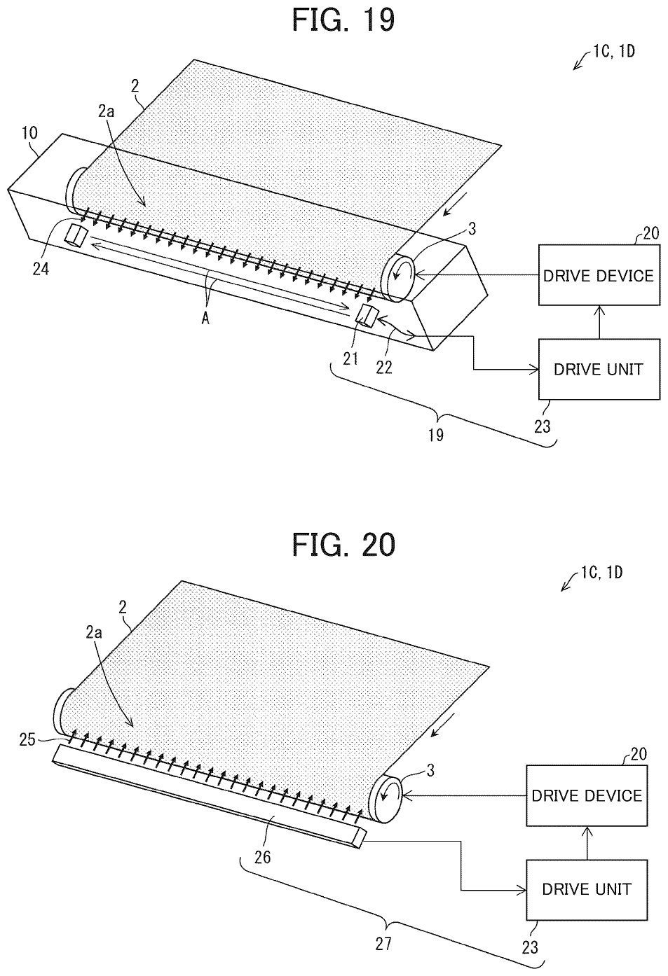

FIG. 19 is a perspective view of the electrostatic control device 19 provided to the winding-type display devices 1C and 1D. Identical reference signs are used to denote the identical constituent elements described before. Such constituent elements will not be elaborated upon repeatedly. Note that FIG. 19 omits the protective film 12 and the read sensor 5 for the sake of clarity.

The winding-type display devices 1C and 1D further include the drive device 20 that drives the first roller 3. The electrostatic control device 19 includes: a point electrostatic control head 21 that reciprocates between one end and another end of the display 2 along the arrows A, and controls charged particles of static electricity generated when the protective film 12 is delaminated from the display 2; a wire 22 that is flexible and connected to the electrostatic control head 21; and a drive unit 23 connected to the wire 22 to drive the drive device 20. The drive device 20 and the drive unit 23 are actually provided in the storage box 10. While the first roller 3 is winding the display 2, the electrostatic control head 21 scans the light-emitting surface 2a of the display 2 along the arrows A to attract or remove static electricity.

FIG. 20 is a perspective view of an electrostatic control device 27 provided to the winding-type display devices 1C and 1D. Identical reference signs are used to denote the identical constituent elements described before. Such constituent elements will not be elaborated upon repeatedly.

The winding-type display devices 1C and 1D may include the electrostatic control device 27 instead of the electrostatic control device 19. The electrostatic control device 27 includes: a linear electrostatic control head 26 extending between one end and another end of the display 2; and the drive unit 23 connected to the electrostatic control head 26 to drive the drive device 20.

While the first roller 3 is winding the display 2, the electrostatic control head 26 attracts or removes static electricity to or from the light-emitting surface 2a of the display 2.

In both of the first and second embodiments, the correction unit 6 corrects the display 2 when the user does not watch the display 2; that is, when the user does not use the winding-type display device. The correction may be made either anytime or periodically. Furthermore, the correction of the display 2 with the correction unit 6 may be instructed by the user himself or herself operating an operation panel. Alternatively, the correction may be made automatically after a predetermined time period has elapsed. Still alternatively, the correction may be made in accordance with an instruction from a server of a manufacturer through the Internet.

Note that, the first and second embodiments exemplify a case where, when the second roller 4 winds the display 2, which is wound by the first roller 3, the second fastener 8B of the display 2 and the second fastening device 9B of the second roller 4 are electrically attached to, and detached from, each other. However, the first and second embodiments shall not be limited to such an example. Alternatively, for example, the surface of the second roller 4 may be provided with a protrusion, and the display 2 is provided with a coupling unit that couples with the protrusion. Hence, the second fastener 8B and the second fastening device 9B may be mechanically attached to, and detached from, each other. Furthermore, the second fastener 8B of the display 2 may be attracted to the surface of the second roller 4 by, for example, static electricity.

### Summary

A winding-type display device according to a first aspect of the present invention includes: a light-emitting device (the display 2) flexible and having a light-emitting surface (2a); a first roller (3) configured to wind the light-emitting device (the display 2); a storage box (10) storing the first roller (3); a correction data obtaining device (the read sensor 5) configured to obtain correction data in the storage box (10) when the light-emitting device (the display 2) is either wound or released, the correction data being used for correcting the light-emitting device (the display 2); a correction device (the correction unit 6) configured to correct light luminance of the light-emitting device (the display 2), in accordance with the correction data obtained by the correction data obtaining device (the read sensor 5); and a second roller (4) disposed in the storage box (10), and configured to wind the light-emitting device (the display 2), wound by the first roller (3), when the correction data obtaining device (the read sensor 5) obtains the correction data on the light-emitting device (the display 2).

Thanks to the above feature, when the correction data is obtained for the light-emitting device wound by the first roller in the storage box, the light-emitting device released from the first roller is wound by the second roller in the storage box. Such a feature allows the light-emitting device to be kept in the storage box when the correction data is obtained for the light- emitting device. Thanks to the feature, the user does not have an odd feeling when the light-emitting device unexpectedly gets in and out of the storage box. Furthermore, the correction data for the light-emitting device can be obtained in the storage box. Hence, the correction data for the light-emitting device is obtained out of view. As a result, the user does not have to designate a time for obtaining the correction data for the light-emitting device and for correcting light luminance of the light-emitting device in accordance with the obtained correction data.

A winding-type display device according to a second aspect of the present invention is the winding-type display device according to the first aspect. The winding-type display device according to the second aspect may further include a forwarding mechanism (the second fastener 8B and the second fastening device 9B) configured to forward, in the storage box (10), the light-emitting device (the display 2) between the first roller (3) and the second roller (4). The forwarding mechanism (the second fastener 8B and the second fastening device 9B) may forward the light-emitting device (the display 2): from the first roller (3) to the second roller (4) when the correction data obtaining device (the read sensor 5) starts to obtain the correction data on the light-emitting device (the display 2); and from the second roller (4) to the first roller (3) after the correction data obtaining device (the read sensor 5) finishes obtaining the correction data on the light-emitting device (the display 2).

Thanks to the above feature, the forwarding mechanism is used when the correction of the light-emitting device starts in the storage box. Such a feature can reliably forward the light-emitting device from the first roller to the second roller. Furthermore, the forwarding mechanism is used when the correction of the light-emitting device ends in the storage box. Such a feature can reliably forward the light-emitting device from the second roller to the first roller.

A winding-type display device according to a third aspect of the present invention is the winding-type display device according to the second aspect. In the winding-type display device according to the third aspect, the forwarding mechanism (the second fastener 8B and the second fastening device 9B) may include: a fastening unit (the second fastener 8B) including a magnetic material provided to a distal end portion of the light-emitting device (the display 2); and an electromagnet (the second fastening device 9B) provided to the second roller (4), and configured to fasten the fastening unit (the second fastener 8B) of the light-emitting device (the display 2) to a surface of the second roller (4) when a current is applied to the electromagnet (the second fastening device 9B).

Thanks to the above feature, the light-emitting device can be easily attached to, and detached from, the second roller simply by ON and OFF of power.

A winding-type device according to a fourth aspect of the present invention is the winding-type display device according to any one of the first to third aspects. In the winding-type display device according to the fourth aspect, the correction data obtaining device (the read sensor 5) may be a light-emission-information reading device (the read sensor 5) configured to read, in the storage box (10), light-emission information on the light-emitting device (the display 2) as the correction data. The correction device (the correction unit 6) may correct the light luminance of the light-emitting device (the display 2) in accordance with the light-emission information, on the light-emitting device (the display 2), read by the light-emission-information reading device (the read sensor 5).

Thanks to the above feature, the light-emission information on the light-emitting device is read in the storage box, and the light-emitting device is corrected in accordance with the read light-emission information. Such a feature makes it possible to appropriately correct the light-emitting device without giving a user an odd feeling.

A winding-type display device according to a fifth aspect of the present invention is the winding-type display device according to the fourth aspect. The winding-type display device according to the fifth aspect may further include a protective film (12) laminated on a light- emitting surface (the light-emitting surface 2a) of the light-emitting device (the display 2). The first roller (3) may wind the protective film (12) and the light-emitting device (the display 12), with the protective film (12) provided outside the light-emitting device (the display 2). The winding-type display device may further include a guide member (the first guide member 13) configured to guide the protective film (12) delaminated from the light-emitting device (the display 2) when the protective film (12) and the light-emitting device (the display 2) are wound by the first roller (3). The light-emission-information reading device (the read sensor 5) may read the light-emission information from the light-emitting surface (the light-emitting surface 2a), of the light-emitting device (the display 2), from which the protective film (12) is delaminated.

When the light-emitting surface (the light-emitting surface 2a) of the light-emitting device (the display 2) is wound by the first roller (3) downstream of a position in which the light-emission-information reading device (the read sensor 5) reads the light-emission information, the protective film (12) guided by the guide member (the first guide member 13) may be laminated again on the light-emitting surface (the light-emitting surface 2a) of the light-emitting device (the display 2).

Thanks to the above feature, the light-emitting surface of the light-emitting device is brought to an appropriate reading position for the light-emission-information reading device. Such a feature makes it possible to appropriately read the light-emission information on the light-emitting device.

A winding-type display device according to a sixth aspect of the present invention is the winding-type display device according to the fifth aspect. The winding-type display device according to the sixth aspect may further include an electrostatic control device disposed between the guide member (the first guide member 13) and the first roller (3), and configured to control static electricity generated when the protective film (12) is delaminated from the light-emitting device (the display 2).

Thanks to the above feature, the electrostatic control device controls static electricity generated when the protective film is delaminated from the light-emitting device. Such a feature makes it possible to smoothly wind and release the light-emitting device.

A winding-type display device according to a seventh aspect of the present invention is the winding-type display device according to any one of the first to sixth aspects. In the winding-type display device according to the seventh aspect, the storage box (11) may have a light-shielding function and a sound-insulating function so that light and sound do not leak outside.

The above feature can reduce leakage of noise (e.g., noise generated when a roller drives) and light (e.g., light emitted when the light-emission information on the light-emitting device is read) to the outside in association with the correction performed in the storage box on the light-emitting apparatus. Such a feature makes it possible to correct the light-emitting device without giving the user an odd feeling.

A winding-type display device according to an eighth aspect of the present invention is the winding-type display device according to the seventh aspect. In the winding-type display device according to the eighth aspect, the storage box (11) may have an inner wall provided with a noise insulating member (11d).

Thanks to the above feature, the noise insulating member is provided to the inner wall of the storage box. Such a feature can easily enhance insulation of the storage box against noise.

A method for correction performed by a winding-type display device according to a ninth aspect of the present invention includes: a first step of winding a light-emitting device, flexible and having a light-emitting surface, around a first roller in a storage box, with the light-emitting surface facing outward; a second step of forwarding an end portion of the light-emitting device, wound by the first roller at the first step, to a second roller provided in the storage box; a third step of winding the light-emitting device by the second roller to which the end portion of the light-emitting device is forwarded at the second step; a forth step of detecting, during the third step, light-emission information by a light-emission-information reading device from the light-emitting surface of the light-emitting device; and a fifth step of correcting light luminance of the light-emitting device in accordance with the light-emission information read by the light-emission-information reading device at the fourth step.

Thanks to the above feature, when the correction is made on the light-emitting device wound by the first roller in the storage box, the light-emitting device released from the first roller is wound by the second roller in the storage box. Such a feature allows the light-emitting device to be kept in the storage box when the correction is made on the light-emitting device. Thanks to the feature, the user does not have an odd feeling when the light-emitting device unexpectedly gets in and out of the storage box. Furthermore, the correction on the light-emitting device can be made in the storage box, so that the correction on the light-emitting device is made out of view. Hence, the user does not have to designate a time for correcting the light-emitting device.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment may be combined to achieve a new technical feature.

### REFERENCE SIGNS LIST

1 Winding-Type Display Device
1A Winding-Type Display Device
1B Winding-Type Display Device
1C Winding-Type Display Device
1D Winding-Type Display Device
2a Light-Emitting Surface
2 Display (Light-Emitting Device)
3 First Roller
4 Second Roller
5 Read Sensor (Light-Emission-Information Reading Device and Correction Data Obtaining Device)
6 Correction Unit (Correction Device)
7 Drawing Device
8A First Fastener
8B Second Fastener
9A First Fastening Device
9B Second Fastening Device
10 Storage Box
10a Opening
11 Storage Box
11b Box Wall
11c Sealing Material
11d Noise Insulating Material
12 Protective Film
13 First Guide Member
14 Second Guide Member
15 Third Guide Member
19 Electrostatic Control Device
20 Drive Device
21 Electrostatic Control Head
22 Wire
23 Drive Unit
26 Electrostatic Control Head
27 Electrostatic Control Device
28 Read Sensor (Light-Emission-Information Reading Device)
29 Wire
30 Read Device
31 Control Device
32 Fourth Guide Member
X Rotation Shaft
Y Rotation Shaft

1. A winding-type display device, comprising:
a light-emitting device flexible and having a light-emitting surface;
a first roller configured to wind the light-emitting device;
a storage box storing the first roller;
a correction data obtaining device configured to obtain correction data in the storage box when the light-emitting device is either wound or released, the correction data being used for correcting the light-emitting device;
a correction device configured to correct light luminance of the light-emitting device, in accordance with the correction data obtained by the correction data obtaining device; and
a second roller disposed in the storage box, and configured to wind the light-emitting device, wound by the first roller, when the correction data obtaining device obtains the correction data on the light-emitting device.

2. The winding-type display device according to claim 1, further comprising
a forwarding mechanism configured to forward, in the storage box, the light-emitting device between the first roller and the second roller,
wherein the forwarding mechanism forwards the light-emitting device: from the first roller to the second roller when the correction data obtaining device starts to obtain the correction data on the light-emitting device; and from the second roller to the first roller after the correction data obtaining device finishes obtaining the correction data on the light-emitting device.

3. The winding-type display device according to claim 2,
wherein the forwarding mechanism includes:
a fastening unit including a magnetic material provided to a distal end portion of the light-emitting device; and
an electromagnet provided to the second roller, and configured to fasten the fastening unit to a surface of the second roller when a current is applied to the electromagnet.

4. The winding-type display device according to claim 1,
wherein the correction data obtaining device is a light-emission-information reading device configured to read, in the storage box, light-emission information on the light-emitting device as the correction data, and
the correction device corrects the light luminance of the light-emitting device in accordance with the light-emission information, on the light-emitting device, read by the light-emission-information reading device.

5. The winding-type display device according to claim 4, further comprising
a protective film laminated on a light-emitting surface of the light-emitting device,
wherein the first roller winds the protective film and the light-emitting device, with the protective film provided outside the light-emitting device,
the winding-type display device further comprises a guide member configured to guide the protective film delaminated from the light-emitting device when the protective film and the light-emitting device are wound by the first roller,
the light-emission-information reading device reads the light-emission information from the light-emitting surface, of the light-emitting device, from which the protective film is delaminated, and
when the light-emitting surface of the light-emitting device is wound by the first roller downstream of a position in which the light-emission-information reading device reads the light-emission information, the protective film guided by the guide member is laminated again on the light-emitting surface of the light-emitting device.

6. The winding-type display device according to claim 5, further comprising
an electrostatic control device disposed between the guide member and the first roller, and configured to control static electricity generated when the protective film is delaminated from the light-emitting device.

7. The winding-type display device according to claim 1,
wherein the storage box has a light-shielding function and a sound-insulating function so that light and sound do not leak outside.

8. The winding-type display device according to claim 7,
wherein the storage box has an inner wall provided with a noise insulating member.

9.A method for correction performed by a winding-type display device, the method comprising:
a first step of winding a light-emitting device, flexible and having a light-emitting surface, around a first roller in a storage box, with the light-emitting surface facing outward;
a second step of forwarding an end portion of the light-emitting device, wound by the first roller at the first step, to a second roller provided in the storage box;
a third step of winding the light-emitting device by the second roller to which the end portion of the light-emitting device is forwarded at the second step;
a forth step of detecting, during the third step, light-emission information by a light-emission-information reading device from the light-emitting surface of the light-emitting device; and
a fifth step of correcting light luminance of the light-emitting device in accordance with the light-emission information read by the light-emission-information reading device at the fourth step.
